(19) United States
(12) Patent Application Publication
(10) Pub. No.: US 2024/0312932 A1
(43) Pub. Date: Sep. 19, 2024

(54) SEMICONDUCTOR DEVICE AND POWER AMPLIFIER INCLUDING THE SAME

(71) Applicant: Samsung Electro-Mechanics Co., Ltd., Suwon-si (KR)

(72) Inventors: Suyeon HAN, Suwon-si (KR); Kyujin CHOI, Suwon-si (KR); Geunyong LEE, Suwon-si (KR); Yoshiyuki TONAMI, Suwon-si (KR); Seungchul PYO, Suwon-si (KR); Kyung Hee HONG, Suwon-si (KR)

(73) Assignee: Samsung Electro-Mechanics Co., Ltd., Suwon-si (KR)

(21) Appl. No.: 18/391,914

(22) Filed: Dec. 21, 2023

(30) Foreign Application Priority Data
Mar. 16, 2023 (KR) 10-2023-0034338

(51) Int. Cl. H01L 23/66; H01L 23/528; H01L 23/532; H01L 27/082; H01L 29/08; H01L 29/417; H01L 29/423; H03F 3/213

(52) U.S. Cl. CPC H01L 23/66; H01L 23/5283; H01L 23/53228; H01L 23/53242; H01L 27/082; H01L 29/0804; H01L 29/0821; H01L 29/41708; H01L 29/42304; H03F 3/213; H01L 2223/6605; H03F 2200/447; H03F 2200/451

(57) ABSTRACT

A semiconductor device is provided. The semiconductor device includes a plurality of unit transistors, each of which is disposed on a semiconductor substrate, and includes a collector electrode configured to output an output signal, a base electrode configured to receive an input signal, an emitter electrode, an emitter junction wiring configured to interconnect the emitter electrodes of the plurality of unit transistors, and a metal pillar disposed to form an interface with the emitter junction wiring, and disposed to be in contact with the emitter junction wiring, and the metal pillar includes a plurality of slits, each of which forms a cavity.

### CROSS-REFERENCE TO RELATED APPLICATIONS

This application claims the benefit 35 USC 119(a) of Korean Patent Application No. 10-2023-0034338 filed on Mar. 16, 2023, in the Korean Intellectual Property Office, the entire disclosure of which is incorporated herein by reference for all purposes.

### BACKGROUND

### 1. Field

The following description relates to a semiconductor device and a power amplifier including the same.

### 2. Description of the Background

With the increase in the usage of mobile devices, data communication has advanced, and the implementation of radio frequency (RF) modules such as, but not limited to, cellular front-end modules (FEMs) has increased. Additionally, as the machine-to-machine (M2M) communication module market is being activated with the rise of the Internet of Things, products and services that use various identification technologies are expected to increase. Accordingly, the market and technology foundation of 5G high-speed communication, a new communication paradigm of communication, is being created, and it is expected that another inflection point will occur.

5G communication may have three advantages: “ultra-high speed and large capacity”, “ultra-low latency”, and “mass connection”. However, millimeter wave (“mmWave”), which is greatly affected by obstacles, has a problem in that it may be difficult to secure communication performance, and in order to improve the performance of wireless signals, robust design, as well as miniaturization, of parts may be beneficial. In this situation, power amplifier integrated circuit (PAIC) components, which determine the performance in 5G communication, have become more important, and it may be necessary to improve communication performance while miniaturizing these components.

The transistor inside the PAIC may amplify the input voltage or current, and transmit the amplified input voltage or current to an external device. However, if the junction between the transistor and the main circuit board is weak, current may not flow smoothly due to damage to the junction, and the quality of the transmission signal may be greatly affected.

Additionally, in order to satisfy the efficiency when operating with a 5G signal, time division duplex (TDD) operation that repeats the ON/OFF operation of the power amplifier may be performed. The temperature of the power amplifier may fluctuate greatly in the ON/OFF section, and cracks may occur at the heterogeneous interface depending on the material of the power amplifier.

The above information is presented as background information only to assist with an understanding of the present disclosure. No determination has been made, and no assertion is made, as to whether any of the above might be applicable as prior art with regard to the disclosure.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, a semiconductor device includes a plurality of unit transistors, each of which is disposed on a semiconductor substrate, each of the plurality of unit transistors includes a collector electrode configured to output an output signal; a base electrode configured to receive an input signal; an emitter electrode; an emitter junction wiring configured to interconnect the emitter electrodes of the plurality of unit transistors; and a metal pillar, disposed to form an interface with the emitter junction wiring, and disposed to be in contact with the emitter junction wiring, wherein the metal pillar includes a plurality of slits each of which includes a cavity.

The plurality of slits may be disposed adjacent to the emitter junction wiring, and may interface the emitter junction wiring and the metal pillar.

The plurality of slits may be disposed apart from each other at preset intervals.

Air may be filled within the plurality of slits to form an air layer.

When viewed in a plan view, at least a first portion of the plurality of slits may be disposed at a position which overlaps the collector electrode of the semiconductor substrate.

At least a second portion of the plurality of slits may be disposed between two adjacent unit transistors of the plurality of unit transistors.

At least a second portion of the plurality of slits may be disposed between collector electrodes of two adjacent unit transistors of the plurality of unit transistors.

A thickness of each of the plurality of slits may be thinner than a thickness of the metal pillar in a thickness direction of the semiconductor substrate.

Each of the plurality of unit transistors may be a bipolar transistor that includes a collector layer disposed in an area where the collector electrode is disposed, a base layer disposed in an area where the base electrode is disposed, and an emitter layer disposed in an area where the emitter electrode is disposed.

The emitter junction wiring may include a gold (Au) material.

In a general aspect, a power amplifier that amplifies a radio frequency (RF) input signal and outputs an RF output signal, the power amplifier includes a plurality of unit transistors, each of which is disposed on a semiconductor substrate, and each of the plurality of unit transistors comprises: a collector electrode configured to output an output signal; a base electrode configured to receive an input signal; an emitter electrode; an emitter junction wiring configured to interconnect the emitter electrodes of the plurality of unit transistors; a metal pillar disposed to form an interface with the emitter junction wiring, and is disposed to be in contact with the emitter junction wiring; and a circuit board on which the plurality of unit transistors are mounted, wherein the metal pillar comprises a plurality of slits each of which comprises a cavity.

The plurality of slits may be disposed adjacent to the emitter junction wiring, and may interface the emitter junction wiring and the metal pillar.

The plurality of slits may be disposed apart from each other at preset intervals.

Air may be filled within the plurality of slits to form an air layer.

When viewed in a plan view, at least a first portion of the plurality of slits may be disposed at a position which overlaps the collector electrode of the semiconductor substrate.

A thickness of each of the plurality of slits may be thinner than a thickness of the metal pillar in a thickness direction of the semiconductor substrate.

In a general aspect, a semiconductor device includes a collector electrode disposed on a collector layer; a base electrode disposed on a base layer; an emitter electrode disposed on an emitter layer; an emitter junction wiring connected to the emitter electrode; and a metal pillar, disposed to contact the emitter junction wiring, wherein the collector electrode, the base electrode, and the emitter electrode are disposed in a single transistor, and wherein a plurality of air cavities are disposed in the metal pillar between the emitter layer and the metal pillar.

The metal pillar may include a copper material.

At least one of the air cavities may be disposed to overlap the collector layer.

The plurality of air cavities may be disposed in a non-overlapping manner with regard to the emitter layer.

Other features and aspects will be apparent from the following detailed description, the drawings, and the claims.

### BRIEF DESCRIPTION OF THE DRAWINGS

FIG. 1 is a layout image which schematically illustrates an example drive amplifier in an example power amplifier, in accordance with one or more embodiments.

FIG. 2 is a top plan view illustrating an example unit transistor in the example drive amplifier illustrated in FIG. 1.

FIG. 3 illustrates a cross-sectional view taken along line III-III′ of FIG. 2.

FIG. 4 illustrates a cross-sectional view taken along line IV-IV′ of FIG. 1.

FIG. 5 illustrates a simulation result obtained by extracting only the emitter junction wiring portion from a drive amplifier structure according to the comparative example and the example embodiment.

FIG. 6 illustrates a simulation result of a 1000-fold exaggerated contour of an emitter junction wiring portion according to an example embodiment for mechanism analysis.

FIG. 7 illustrates a cross-sectional image of an example semiconductor device, in accordance with one or more embodiments, showing a plurality of unit transistors in an example power amplifier and a plurality of slits corresponding thereto.

Throughout the drawings and the detailed description, unless otherwise described, the same reference numerals refer to the same elements. The drawings may not be to scale, and the relative size, proportions, and depiction of elements in the drawings may be exaggerated for clarity, illustration, and convenience.

### DETAILED DESCRIPTION

Hereinafter, while examples of the present disclosure will be described in detail with reference to the accompanying drawings, it is noted that examples are not limited to the same.

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of this disclosure. For example, the sequences of operations described herein are merely examples, and are not limited to those set forth herein, but may be changed as will be apparent after an understanding of this disclosure, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of this disclosure.

Throughout the specification, when an element, such as a layer, region, or substrate is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items; likewise, “at least one of” includes any one and any combination of any two or more of the associated listed items.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms, such as “above,” “upper,” “below,” “lower,” and the like, may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above,” or “upper” relative to another element would then be “below,” or “lower” relative to the other element. Thus, the term “above” encompasses both the above and below orientations depending on the spatial orientation of the device. The device may also be oriented in other ways (rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

Herein, it is noted that use of the term “may” with respect to an example, for example, as to what an example may include or implement, means that at least one example exists in which such a feature is included or implemented while all examples are not limited thereto.

The features of the examples described herein may be combined in various ways as will be apparent after an understanding of this disclosure. Further, although the examples described herein have a variety of configurations, other configurations are possible as will be apparent after an understanding of this disclosure.

One or more examples may provide a semiconductor device and a power amplifier including the same that decreases the possibility of cracks in a transistor by reducing stress of a transistor inside the power amplifier by relieving the thermal stress in a structural aspect.

In the one or more examples, cracks may be decreased by reducing stress of a transistor inside the power amplifier by relieving the thermal stress in a structural aspect.

In the one or more examples, when polybenzoxazole (PBO), which is an insulation material in contact with emitter junction wiring within the power amplifier, expands, the slit region in the cavity structure contracts, and thereby the stress in a portion vulnerable to thermal stress may be relieved.

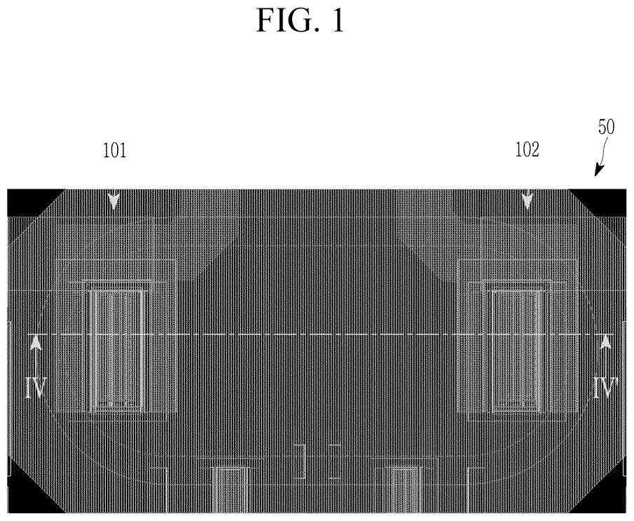

FIG. 1 is a layout image schematically illustrating an example drive amplifier in an example power amplifier, in accordance with one or more embodiments.

A power amplifier integrated circuit (PAIC) that is implemented as a power amplifier is an electronic device that integrates a power amplifier into a single chip. It may be implemented in wireless communication systems such as, but not limited to, mobile phones and Wi-Fi routers to amplify signals and increase system range. PAICs may deliver high output power while maintaining good linearity and efficiency, and may be available in a variety of power levels and frequency bands to support a variety of applications.

Within the power amplifier, a drive amplifier 50 may provide the necessary input signals to a power amplifier core, and may be used to provide the necessary gain and power to drive the power amplifier core. An RF input signal may be first amplified by the drive amplifier before being coupled to the power amplifier core.

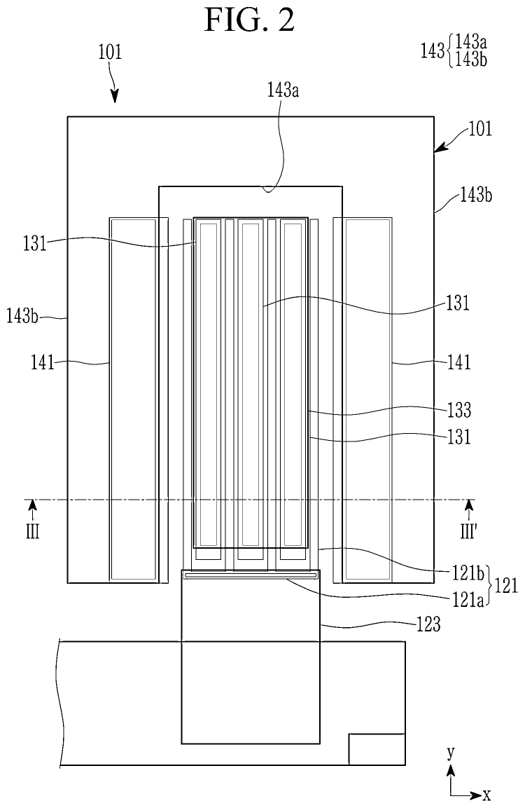

Referring to FIG. 1, the drive amplifier 50 may include two unit transistors 101 and 102 that are spaced apart from each other on a plane, and are electrically connected in parallel. That is, in each of the two unit transistors 101 and 102, a base electrode 121 (refer to FIG. 2) may be connected to a common input wire to receive a common RF input signal, and a collector electrode 141 (refer to FIG. 2) may be connected to a common output wire to output an amplified RF output signal. Additionally, in each of the two unit transistors 101 and 102, an emitter electrode 131 (refer to FIG. 2) may be connected to ground. Although only two unit transistors 101 and 102 are illustrated in FIGS. 1 and 2, this is only an example, and one transistor or more than two transistors may be implemented.

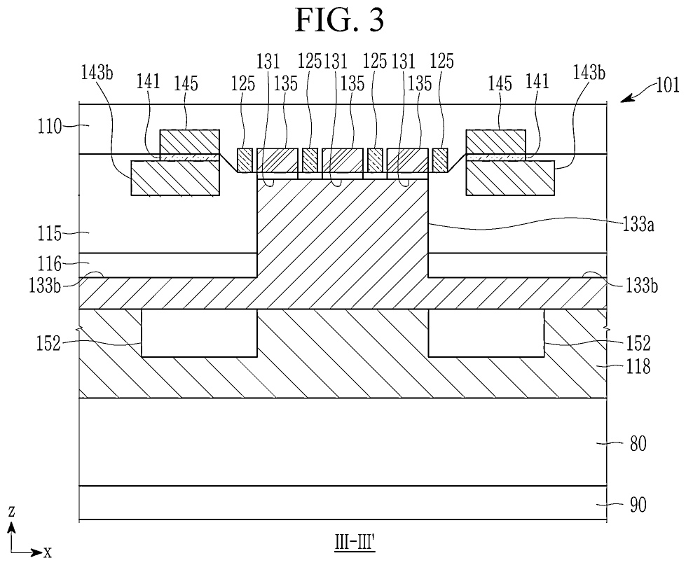

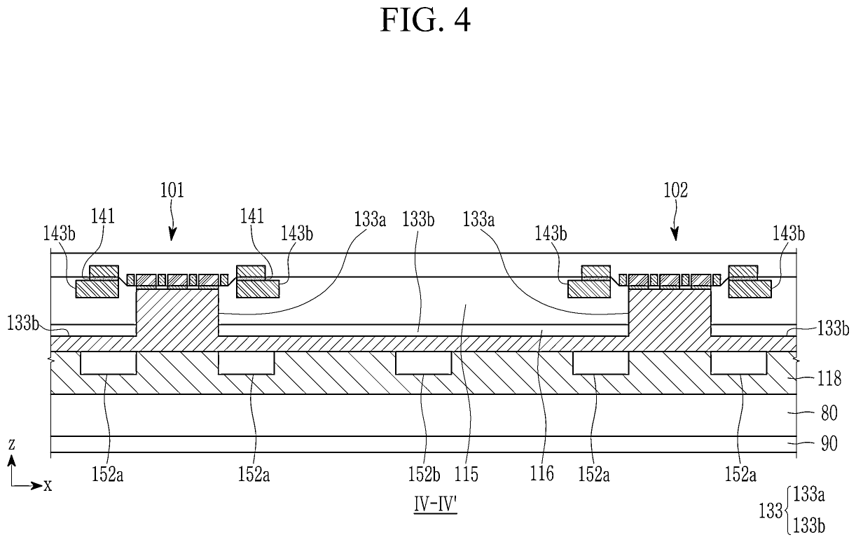

FIG. 2 is a top plan view illustrating an example unit transistor of the drive amplifier illustrated in FIG. 1. FIG. 3 is a cross-sectional view taken along line III-III′ of FIG. 2. FIG. 4 is a cross-sectional view taken along line IV-IV′ of FIG. 1.

Referring to FIG. 2, a unit transistor 101, in accordance with one or more embodiments, may be a bipolar transistor, and may include the base electrode 121, the emitter electrode 131, and the collector electrode 141. The base electrode 121 may be connected to the input wire or connection where the RF input signal is input, and the collector electrode 141 may be connected to the output wire or connection where the RF output signal is output. In an example, the emitter electrode 131 may be connected to ground through an emitter junction wiring 133.

The unit transistor 101 may include a semiconductor substrate 110 (refer to FIG. 3), and the base electrode 121, the emitter electrode 131, and the collector electrode 141 may be disposed on the semiconductor substrate 110. An input RF signal is input to the base electrode 121, and an output RF signal is output from the collector electrode 141.

The base electrode 121 may be connected to a base wire 123, the emitter electrode 131 may be connected to the emitter junction wiring 133, and the collector electrode 141 may be connected to a collector wire 143 (143a and 143b). The base wire 123, the emitter junction wiring 133, and the collector wire 143 may be positioned in different layers, respectively, from the base electrode 121, the emitter electrode 131, and the collector electrode 141 along a thickness direction of the semiconductor substrate 110 (z-axis direction in the drawing, hereinafter, also referred to as the thickness direction of the substrate) (refer to FIG. 3).

The base electrode 121 includes a coupling portion 121a and a plurality of branch portions 121b that are positioned on a same plane. The plurality of branch portions 121b may extend parallel to each other in a first direction (the y-axis direction in the drawing) and may be connected to each other by the coupling portion 121a. The coupling portion 121a may extend in a second direction (the x-axis direction in the drawing) that is perpendicular to the direction along which the plurality of branch portions 121b extend. The base wire 123, which is positioned in a layer different from a layer where the base electrode 121 is positioned, may have an overlapping portion in the thickness direction of the substrate at the coupling portion 121a of the base electrode 121, and may be connected to the coupling portion 121a.

The emitter electrode 131 includes a plurality of elongated rectangular electrodes each extending in the first direction (the y-axis direction in the drawing). Each of the plurality of emitter electrodes 131 may be disposed between the plurality of branch portions 121b of the base electrode 121 when viewed from a plan view. Long sides of the emitter electrode 131 may be disposed adjacent to both sides of the branch portion 121b of the base electrode 121, one short side of the emitter electrode 131 may be disposed adjacent to the coupling portion 121a of the base electrode 121, and a remaining short side of the emitter electrode 131 may be opened. Accordingly, the emitter electrode 131 may be disposed to have three edges that are surrounded by the base electrode 121.

The collector electrode 141 may be disposed on both outer sides of the base electrode 121, respectively, when viewed from a plan view. The collector electrode 141 may be formed of a rectangular electrode extending in the first direction (the y-axis direction in the drawing). The collector electrode 141 of the rectangular shape may extend along the first direction by a length of the base electrode 121. A width of each collector electrode 141 in the second direction (the x-axis direction in the drawing) may be narrower than an entire width of the base electrode 121 according to the second direction, and wider than a width of each emitter electrode 131 according to the second direction.

The collector wire 143 (143a and 143b) may be positioned in a layer different from a layer where the collector electrode 141 is positioned, and may have an overlapping portion with at least a part of the collector electrode 141 in the thickness direction of the substrate, and may be connected to each other. The collector wiring 143 may at least partially overlap the collector electrode 141, and may include a pair of connection portions 143b extending in the first direction and a common portion 143a extending in the second direction and connecting the connection portions 143b. Accordingly, when viewed from a plan view, the collector wire 143 may be disposed to surround the base electrode 121 and the emitter electrode 131 by three edges, and the common portion 143a of the collector wire 143 may be disposed to face the coupling portion 121a of the base electrode 121.

FIG. 3 illustrates an enlarged cross-sectional view of an example unit transistor in an example drive amplifier, in accordance with one or more embodiments.

Referring to FIG. 3, the unit transistor 101, in accordance with one or more embodiments, may form a part of the semiconductor device, in accordance with one or more embodiments, as the base electrode 121 (refer to FIG. 2), the emitter electrode 131, and the collector electrode 141 are formed on the semiconductor substrate 110. FIG. 3 illustrates that the base electrode 121, the emitter electrode 131, and the collector electrode 141 formed on the semiconductor substrate 110 are positioned toward the printed circuit board 90, such that the semiconductor device may be mounted on a printed circuit board 90.

The emitter electrode 131 may be interconnected with the emitter electrode 131 of another unit transistor 102 (refer to FIG. 4) through the emitter junction wiring 133, and a connection end of the semiconductor device may be configured in the form of a bump by covering the emitter junction wiring 133 by a metal pillar 118. The semiconductor device may be mounted on the printed circuit board 90 as the metal pillar 118 is bonded to the printed circuit board 90 by a solder 80. At this time, the metal pillar 118 may be connected to a ground wire on the printed circuit board 90 while forming a ground layer. In an example, the emitter junction wiring 133 may include gold (Au), and the metal pillar 118 may include copper (Cu).

In the unit transistor 101, a collector layer 145, a base layer 125, and an emitter layer 135 are stacked on the semiconductor substrate 110. In an example, the collector layer 145 may be an n-type, the base layer 125 may be a p-type, and the emitter layer 135 may be an n-type silicon layer.

The collector electrode 141 may be disposed on the collector layer 145, the base electrode 121 may be disposed on the base layer 125, and the emitter electrode 131 may be disposed on the emitter layer 135. With reference to a surface of the semiconductor substrate 110 in the thickness direction of the substrate, the base electrode 121 may be positioned higher than the collector electrode 141, and the emitter electrode 131 may be positioned higher than the base electrode 121. That is, with reference to the printed circuit board 90, the emitter electrode 131 may be positioned closer to the printed circuit board 90 than the base electrode 121, and the base electrode 121 may be positioned closer to the printed circuit board 90 than the collector electrode 141.

The collector wire 143 may be disposed on the collector electrode 141. The collector wire 143 may be formed to be thicker and wider than the collector electrode 141. Since the collector electrode 141 may be respectively disposed at both sides, interposing the base electrode 121 and the emitter electrode 131, the collector wire 143 may include, corresponding thereto, the pair of connection portions 143b respectively disposed at both sides, interposing the base electrode 121 and the emitter electrode 131.

The emitter junction wiring 133 may be disposed on the emitter electrode 131. The emitter junction wiring 133 includes a junction portion 133a connected to the emitter electrode 131 and wiring portions 133b which extend to interconnect emitter electrodes of different unit transistors. The junction portion 133a may protrude from the wiring portions 133b in the thickness direction of the substrate, and may be connected to the emitter electrode 131. Accordingly, the emitter junction wiring 133 may avoid the collector wire 143, and may be connected to the emitter electrode 131.

Insulation materials 115 and 116 may be filled between the emitter junction wiring 133 (133a, 133b) and the collector wire 143 (143b). The insulation materials 115 and 116 may be filled on the semiconductor substrate 110 to cover the collector wire 143, the collector electrode 141, the base electrode 121. In a non-limited example, the insulation materials 115 and 116 may include a first insulation material 115 containing silicon nitride (SiN), and a second insulation material 116 containing polybenzoxazole (PBO). The first insulation material 115 may be positioned on the semiconductor substrate 110 to cover the collector wire 143, and the second insulation material 116 may be positioned between the wiring portion 133b of the emitter junction wiring 133 and the first insulation material 115.

In the one or more embodiments, the wiring portion 133b of the emitter junction wiring 133 is disposed to form an interface with, and be in contact with, the metal pillar 118. A plurality of slits 152 may be disposed in the metal pillar 118 to be adjacent to the interface. Each of the plurality of slits 152 may have a hollow cavity structure, and may be disposed apart from each other at a preset interval. Additionally, in an example, air may be filled in each of the plurality of slits 152 having the cavity structure, and accordingly, an air layer may exist between the emitter junction wiring 133 and the metal pillar 118.

FIG. 4 illustrates an enlarged cross-sectional view of a pair of example unit transistors in an example drive amplifier, in accordance with one or more embodiments.

Referring to FIG. 4, when viewed in a plan view of the substrate, the plurality of slits 152 may include the slits 152a disposed at a position overlapping the collector electrode 141. Additionally, the plurality of slits 152 may include a slit 152b disposed between the two unit transistors 101 and 102 which are disposed adjacent to each other. That is, the slits 152a and 152b may be disposed adjacent to the wiring portion 133b of the emitter junction wiring 133, on both sides of the junction portion 133a of the emitter junction wiring 133. Additionally, the slit 152b may be disposed between the connection portions 143b of the collector wires 143 of the two unit transistors 101 and 102 that are different from each other.

In connection with thicknesses in the thickness direction of the substrate (z-axis direction in the drawing), a thickness of each of the plurality of slits 152 may be thinner than a thickness of the metal pillar 118. Accordingly, the metal pillar 118 may continue along the second direction (x-axis direction in the drawing) without being discontinued by the slit 152. Additionally, each of the plurality of slits 152 may have a rectangular cross-section, and when viewed in a plan view of the substrate, each of the plurality of slits 152 may be formed to extend as much as the width of the metal pillar 118 along the y-axis direction.

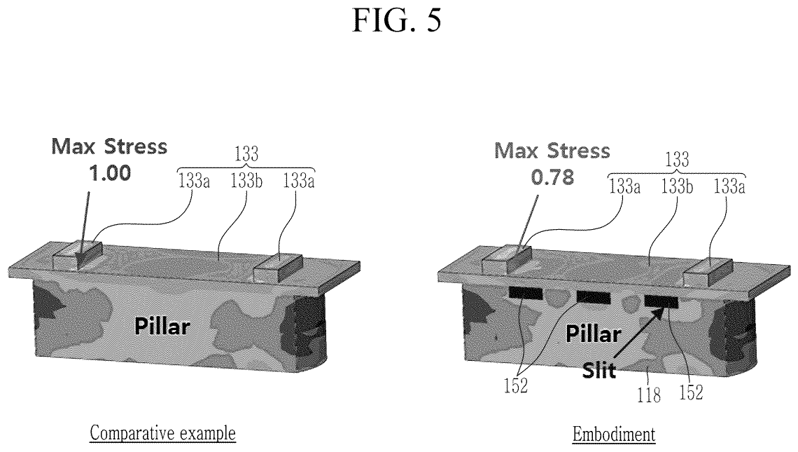

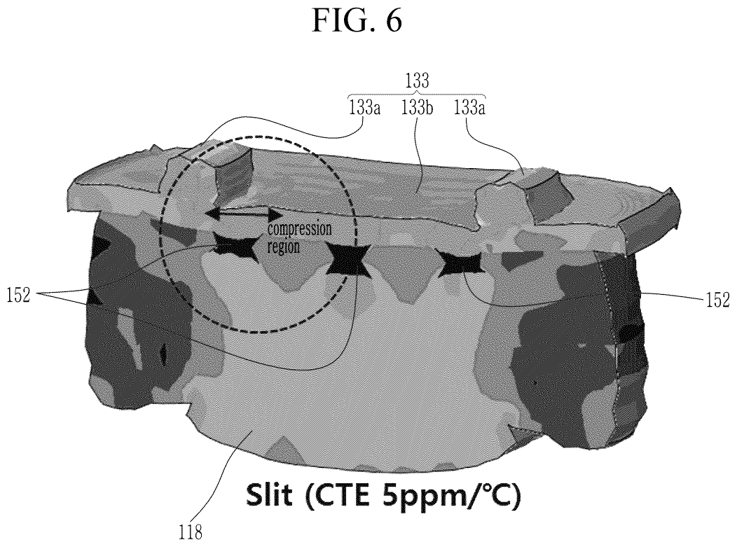

FIG. 5 illustrates a simulation result obtained by extracting only the emitter junction wiring portion from a drive amplifier structure according to the comparative example and the example embodiment. FIG. 6 is a simulation result showing a 1000-fold exaggerated contour of an emitter junction wiring portion according to an example embodiment for mechanism analysis.

Referring to FIG. 5, the comparative example (structure on the left in the drawing) has a structure in which no slits are formed on the metal pillar, and the example embodiment (structure on the right in the drawing) has a structure in which a plurality of slits 152 are formed on the metal pillar 118. While the maximum stress of the concave edge formed by the junction portion 133a and the wiring portion 133b in the emitter junction wiring 133 of the comparative example was 1.00, the maximum stress of the concave edge formed by the junction portion 133a and the wiring portion 133b in the emitter junction wiring 133 of the embodiment was 0.78. Here, since the slit 152 has a cavity structure filled with air, the coefficient of thermal expansion of the slit 152 is set to 5 ppm/° C., which is the level of air.

A lot of heat may be generated in the ground layer while the power amplifier conducts an ON/OFF operation. The greater the temperature change during the ON/OFF operation and the greater the CTE mismatch (mismatch of the coefficient of thermal expansion) between materials, the greater the level of stress generated.

Referring to FIG. 6, in the one or more examples, it may be confirmed that, when polybenzoxazole (PBO), an insulating material in contact with the emitter junction wiring 133, expands, a portion vulnerable to the thermal stress may be relieved from the stress since the region of the slit 152 contracts.

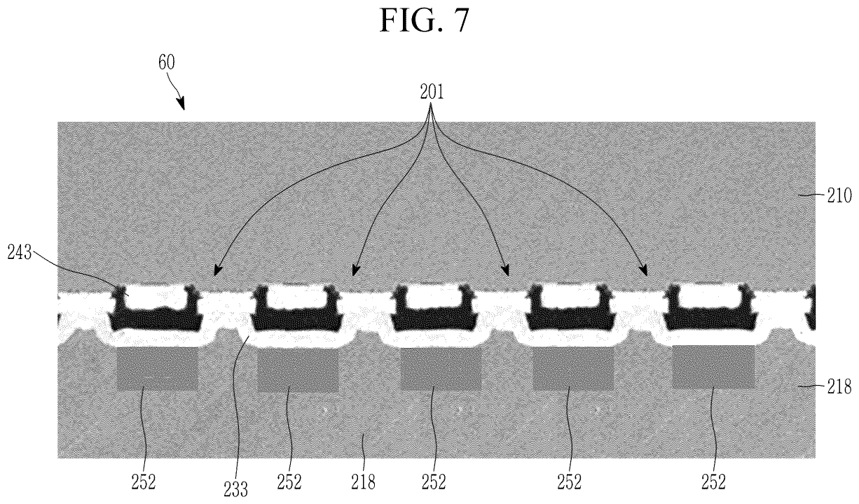

FIG. 7 illustrates a cross-sectional image of an example semiconductor device, in accordance with one or more embodiments, showing a plurality of example unit transistors in an example power amplifier and a plurality of slits corresponding thereto.

Referring to FIG. 7, a plurality of unit transistors 201 are disposed in a power amplifier 60, in accordance with one or more embodiments, the plurality of unit transistors 201 are interconnected with each other by an emitter junction wiring 233. The emitter junction wiring 233 includes a junction portion in connection with the emitter electrode, and a wiring portion extending to interconnect emitter electrodes of different unit transistors 201.

The structure of each unit transistor 201 may be the same as described with reference to FIG. 2 and FIG. 3. Accordingly, the structure of the unit transistor 201 is not further described and illustrated herein. In this example embodiment, compared to the example embodiment shown in FIG. 4, a larger number of unit transistors 201 are arranged relatively closer to each other.

The wiring portion of the emitter junction wiring 233 may be disposed to form an interface with, and be in contact with, a metal pillar 218, and a plurality of slits 252 may be disposed in the metal pillar 218 to be adjacent to the interface. Each of the plurality of slits 252 may have a hollow cavity structure, and may be disposed apart from each other at a preset interval. Additionally, air may be filled in each of the plurality of slits 252 having the cavity structure, and accordingly, an air layer may exist between the emitter junction wiring 233 and the metal pillar 218.

Each, or at least one, of the plurality of slits 252 may be disposed at a position overlapping the collector wire 243 or the collector electrode when viewed from a plane of the substrate. That is, the slits 252 may be disposed adjacent to the wiring portion of the emitter junction wiring 233, on both sides of the junction portion 233a of the emitter junction wiring 233.

While specific examples have been shown and described above, it will be apparent after an understanding of this disclosure that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A semiconductor device, comprising:
a plurality of unit transistors, each of which is disposed on a semiconductor substrate, each of the plurality of unit transistors comprising:
a collector electrode configured to output an output signal;
a base electrode configured to receive an input signal;
an emitter electrode;
an emitter junction wiring configured to interconnect the emitter electrodes of the plurality of unit transistors; and
a metal pillar, disposed to form an interface with the emitter junction wiring, and disposed to be in contact with the emitter junction wiring,
wherein the metal pillar comprises a plurality of slits each of which comprises a cavity.

2. The semiconductor device of claim 1, wherein the plurality of slits are disposed adjacent to the emitter junction wiring, and interfaces the emitter junction wiring and the metal pillar.

3. The semiconductor device of claim 1, wherein the plurality of slits are disposed apart from each other at preset intervals.

4. The semiconductor device of claim 1, wherein air is filled within the plurality of slits to form an air layer.

5. The semiconductor device of claim 1, wherein, when viewed in a plan view, at least a first portion of the plurality of slits is disposed at a position which overlaps the collector electrode of the semiconductor substrate.

6. The semiconductor device of claim 5, wherein at least a second portion of the plurality of slits is disposed between two adjacent unit transistors of the plurality of unit transistors.

7. The semiconductor device of claim 5, wherein at least a second portion of the plurality of slits is disposed between collector electrodes of two adjacent unit transistors of the plurality of unit transistors.

8. The semiconductor device of claim 1, wherein a thickness of each of the plurality of slits is thinner than a thickness of the metal pillar in a thickness direction of the semiconductor substrate.

9. The semiconductor device of claim 1, wherein each of the plurality of unit transistors is a bipolar transistor that comprises:
a collector layer disposed in an area where the collector electrode is disposed,
a base layer disposed in an area where the base electrode is disposed, and an
emitter layer disposed in an area where the emitter electrode is disposed.

10. The semiconductor device of claim 1, wherein the emitter junction wiring comprises a gold (Au) material.

11. A power amplifier that amplifies a radio frequency (RF) input signal and outputs an RF output signal, the power amplifier comprising:
a plurality of unit transistors, each of which is disposed on a semiconductor substrate, and each of the plurality of unit transistors comprises:
a collector electrode configured to output an output signal;
a base electrode configured to receive an input signal;
an emitter electrode;
an emitter junction wiring configured to interconnect the emitter electrodes of the plurality of unit transistors;
a metal pillar disposed to form an interface with the emitter junction wiring, and is disposed to be in contact with the emitter junction wiring; and
a circuit board on which the plurality of unit transistors are mounted,
wherein the metal pillar comprises a plurality of slits each of which comprises a cavity.

12. The power amplifier of claim 11, wherein the plurality of slits are disposed adjacent to the emitter junction wiring, and interfaces the emitter junction wiring and the metal pillar.

13. The power amplifier of claim 11, wherein the plurality of slits are disposed apart from each other at preset intervals.

14. The power amplifier of claim 11, wherein air is filled within the plurality of slits to form an air layer.

15. The power amplifier of claim 11, wherein when viewed in a plan view, at least a first portion of the plurality of slits is disposed at a position which overlaps the collector electrode of the semiconductor substrate.

16. The power amplifier of claim 11, wherein a thickness of each of the plurality of slits is thinner than a thickness of the metal pillar in a thickness direction of the semiconductor substrate.

17. A semiconductor device, comprising:
a collector electrode disposed on a collector layer;
a base electrode disposed on a base layer;
an emitter electrode disposed on an emitter layer;
an emitter junction wiring connected to the emitter electrode; and
a metal pillar, disposed to contact the emitter junction wiring,
wherein the collector electrode, the base electrode, and the emitter electrode are disposed in a single transistor, and
wherein a plurality of air cavities are disposed in the metal pillar between the emitter layer and the metal pillar.

18. The semiconductor device of claim 17, wherein the metal pillar comprises a copper material.

19. The semiconductor device of claim 17, wherein at least one of the air cavities is disposed to overlap the collector layer.

20. The semiconductor device of claim 17, wherein the plurality of air cavities are disposed in a non-overlapping manner with regard to the emitter layer.
